(19) United States
(12) Patent Application Publication
(10) Pub. No.: US 2011/0133330 A1
(43) Pub. Date: Jun. 9, 2011

(54) LOW TEMPERATURE CURING COMPOSITIONS

(75) Inventors: Jie Bai, Carlsbad, CA (US); Shashi K. Gupta, Tustin, CA (US)

(73) Assignee: Henkel Corporation, Rocky Hill, CT (US)

(21) Appl. No.: 13/027,747

(22) Filed: Feb. 15, 2011

Related U.S. Application Data
(63) Continuation of application No. PCT/US2009/004568, filed on Aug. 8, 2008.
(60) Provisional application No. 61/087,306, filed on Aug. 8, 2008.

(51) Int. Cl. H01L 23/28; C08F 122/40; C08L 39/00; H01B 1/12; B32B 37/02; B32B 37/12; B32B 37/14; H05K 3/00

(52) U.S. Cl. 257/734; 526/262; 526/259; 524/850; 252/500; 156/331.5; 257/E23.116

(57) ABSTRACT

The present invention relates to thermosetting resin compositions that include maleimide-, nadimide- or itaconimide-containing compounds and a metal/carboxylate complex and a peroxide, which is curable at a low temperature at relative short period of time, such as less than about 100° C., for instance 55-70° C., over a period of time of about 30 to 90 minutes. The invention further provides methods of preparing such compositions, methods of applying such compositions to substrate surfaces, and packages and assemblies prepared therewith for connecting microelectronic circuitry.

### BACKGROUND OF THE INVENTION

1. Field of the Invention

The present invention relates to thermosetting resin compositions that include maleimide-, nadimide- or itaconimide-containing compounds and a metal/carboxylate complex and a peroxide, which is curable at a low temperature, such as less than about 100° C., for instance in the range of 55-70° C., in a relative short period of time, such as over a period of time of about 30 to 90 minutes.

2. Brief Description of Related Technology

Thermosetting resins are commonly used in adhesive formulations due to the outstanding performance properties which can be achieved by forming a fully crosslinked, three-dimensional network. These properties include cohesive bond strength, resistance to thermal and oxidative damage, and low moisture uptake. As a result, common thermosetting resins such as epoxy resins, bismaleimide resins, and cyanate ester resins have been employed extensively in applications ranging from structural adhesives (e.g., construction and aerospace applications) to microelectronics (e.g., die-attach and underfill applications).

Bismaleimides occupy a prominent position in the spectrum of thermosetting resins. Bismaleimides have been used for the production of moldings and adhesive joints, heat-resistant composite materials, and high temperature coatings. More recently, Henkel Corporation commercialized a number of products based in part on certain bismaleimides for the attachment of semiconductor chips to circuit boards, which have received favorable responses from within the microelectronic industry. These products are covered in one or more of U.S. Pat. Nos. 5,789,757 (Husson), 6,034,194 (Dershem), 6,034,195 (Dershem) and 6,187,886 (Husson).

U.S. Pat. No. 5,298,562 reports the use of magnesium methacrylate to cure cis1,4-polybutadiene elastomers is described in “Elastic Properties and Structures of Polybutadiene Vulcanized with Magnesium Methacrylate”, J. Appl. Polym. Sci., 16, 505-518 (1972). The '562 patent also reports that A. A. Dontsov, “General Regularities of Heterogeneous Vulcanization”, Rubbercon '77, International Rubber Conference, 2, 26-1 through 26-12 (1977) describes vulcanizable compositions of styrene-butadiene rubber or ethylene-propylene rubber cured with a magnesium, sodium, zinc or cadmium salt of methacrylic, maleic or betaphenyl acrylic acids, together with free radical initiators such as dicumyl peroxide.

In addition, the '562 patent itself speaks to the use of calcium acrylate and methacrylate as cross-linking agents, and spells out as an objective the provision of an improved free radical curable composition having good chemical and heat resistance. This objective is achieved by a composition that contains a halogenated polyethylene polymer or crosslinked with a calcium di(meth)acrylate crosslinking agent, and is reported to improve tensile strength and scorch resistance over other prior art compositions employing different crosslinking coagents. The '562 patent also speaks to new and improved processes for the preparation of free radical curable calcium di(meth)acrylate crosslinked halogenated polyethylene copolymers.

And U.S. Pat. No. 5,776,294 describes the use of metal salts of certain α,β-ethylenically unsaturated carboxylic acids, specifically the metal salts of acrylic and methacrylic acids, as crosslinking coagents, to yield cured elastomer compositions with improved adhesive properties with respect to polar surfaces. The adhesive properties reported include lap shear adhesion to cold rolled steel, stainless steel, brass, zinc, aluminum, and nylon fiber. Examples of the metal component for those metal salts of acrylic and methacrylic acids are reported as zinc, magnesium, sodium, potassium, calcium, barium, cobalt, copper, aluminum and iron. See also U.S. Pat. No. 6,194,504, which claims a composition comprising MAₙ, salt in particulate form having improved dispersibility in elastomers, where M is a zinc, calcium, magnesium, potassium, sodium, lithium, iron, zirconium, aluminum, barium and bismuth; A is acrylate or methacrylate; and n is 1-4; where the salt encapsulated with a polymer selected from polybutadiene, hydroxy-terminated polybutadiene, polybutadiene dimethacrylate, ethylene-butylene diacrylate, natural rubber, polybutene, and EPDM; and where the polymer encapsulates the salt upon drying a polymeric solution of the salt, the polymer and an organic solvent.

Notwithstanding the state-of-the-technology, it would be desirable to be able to provide a lower temperature cure profile for bismaleimide compositions for microelectronic packaging and assembly applications, because at least in part the sensitive nature of the semiconductor die, the circuitry embedded thereon, the substrates on which and to which the semiconductor die is to be attached and the electrical interconnections formed therebetween either by way of wire bonds or solder balls.

Until now, this is not believed to have been reported or observed in such composition types.

### SUMMARY OF THE INVENTION

The present invention is directed to curable compositions, which include:

a. a curable component comprising one or more of a maleimide-, nadimide- or itaconimide-containing compound comprising

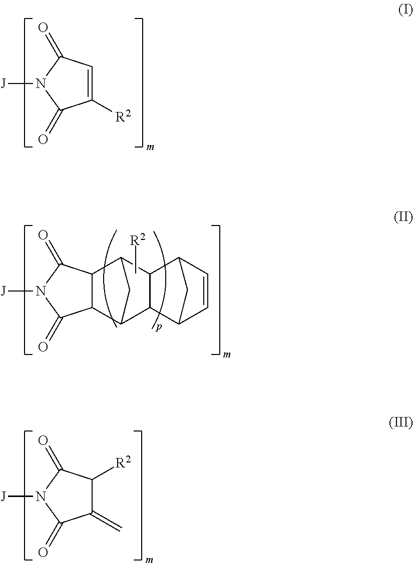

respectively, where:

m=1-15,

p=0-15,
each R² is independently selected from hydrogen or lower alkyl, and J comprises a monovalent or a polyvalent moiety comprising organic or organosiloxane radicals, and combinations thereof; and

b. a curative component comprising the combination of a metal/carboxylate complex and a peroxide.

The present invention also provides a method of making the inventive compositions, a method of adhesively attaching one substrate, such as a semiconductor chip, to another substrate, such as a another semiconductor chip, a carrier substrate or a circuit board, cured reaction products of the inventive compositions, and an article of manufacture, and in particular, a semiconductor chip which is attached to and in electrical interconnection with another semiconductor chip, a carrier substrate or a circuit board, where the attachment is made at least in part by the inventive composition.

### DETAILED DESCRIPTION OF THE INVENTION

As noted above, the present invention is directed to curable compositions, which include:

a. a curable component comprising one or more of a maleimide-, nadimide- or itaconimide-containing compound comprising

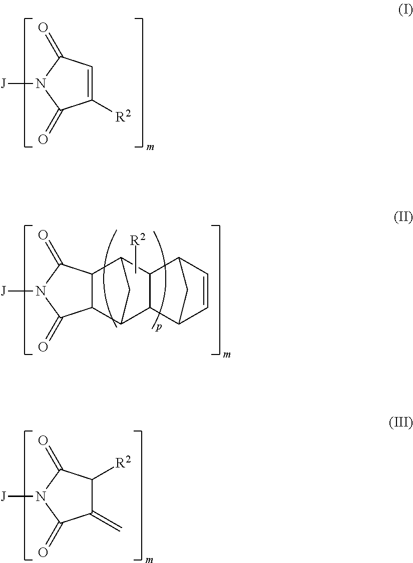

respectively, where:
m=1-15,

p=015,
each R² is independently selected from hydrogen or lower alkyl, and J comprises a monovalent or a polyvalent moiety comprising organic or organosiloxane radicals, and combinations of two or more thereof; and

b. a curative component comprising the combination of a metal/carboxylate complex and a peroxide.

The “J” appendage of the maleimide-, nadimide- or itaconimide-containing compound may be viewed as a monovalent or polyvalent radical selected from hydrocarbyl, substituted herteroatom-containing hydrocarbyl, hydrocarbylene, substituted hydrocarbylene, heteroatom-containing hydrocarbylene, substituted heteroatom-containing hydrocarbylene, polysiloxane, polysiloxane-polyurethane block copolymer, and combinations thereof, optionally containing one ore more linkers selected from a covalent bond, —O—, —S—, —NR—, —O—C(O)—, —O—C(O)—O—, —O—C(O)—NR—, —NR—C(O)—, —NR—C(O)—O—, —NR—C(O)—NR—, —S—C(O)—, —S—C(O)—O—, —S—C(O)—NR—, —S(O)—, —S(O)₂—, —O—S(O)₂—, —O—S(O)₂—O—, —O—S(O)₂—NR—, —O—S(O)—, —O—S(O)—O—, —O—S(O)—NR—, —O—NR—C(O)—, —O—NR—C(O)—O—, —O—NR—C(O)—NR—, —NR—O—C(O)—, —NR—O—C(O)—O—, —NR—O—C(O)—NR—, —O—NR—C(S)—, —O—NR—C(S)—O—, —O—NR—C(S)—NR—, —NR—O—C(S)—, —NR—O—C(S)—O—, —NR—O—C(S)—NR—, —O—C(S)—, —O—C(S)—O—, —O—C(S)—NR—, —NR—C(S)—, —NR—C(S)—O—, —NR—C(S)—NR—, —S—S(O)₂—, —S—S(O)₂—O—, —S—S(O)₂—NR—, —NR—O—S(O)—, —NR—O—S(O)—O—, —NR—O—S(O)—NR—, —NR—O—S(O)₂—, —NR—O—S(O)₂—O—, —NR—O—S(O)₂—NR—, —O—NR—S(O)—, —O—NR —S(O)—O—, —O—NR—S(O)—NR—, —O—NR—S(O)₂—O—, —O—NR—S(O)₂—NR—, —O—NR—S(O)₂—, —O—P(O)R₂—, —S—P(O)R₂—, —NR—P(O)R₂—, where each R is independently hydrogen, alkyl or substituted alkyl, and combinations of any two or more thereof.

When one or more of the above described monovalent or polyvalent groups contain one or more of the above described linkers to form the “J” appendage of a maleimide, nadimide or itaconimide group, as readily recognized by those of skill in the art, a side variety of linkers can be produced, such as, for example, oxyalkyl, thioalkyl, aminoalkyl, carboxylalkyl, oxyalkenyl, thioalkenyl, aminoalkenyl, carboxyalkenyl, oxyalkynyl, thioalkynyl, aminoalkynyl, carboxyalkynyl, oxycycloalkyl, thiocycloalkyl, aminocycloalkyl, carboxycycloalkyl, oxycloalkenyl, thiocycloalkenyl, aminocycloalkenyl, carboxycycloalkenyl, heterocyclic, oxyheterocyclic, thioheterocyclic, aminoheterocyclic, carboxyheterocyclic, oxyaryl, thioaryl, aminoaryl, carboxyaryl, heteroaryl, oxyheteroaryl, thioheteroaryl, aminoheteroaryl, carboxyheteroaryl, oxyalk, aryl, thioalkylaryl, aminoalkylaryl, carboxyalkylaryl, oxyarylalkyl, thioarylalkyl, aminoarylalkyl, carboxyarylalkyl, oxyarylalkenyl, thioarylalkenyl, aminoarylalkenyl, carboxyarylalkenyl, oxyalkenylaryl, thioalkenylaryl, aminoalkenylaryl, carboxyalkenylaryl, oxyarylalkynyl, thioarylalkynyl, aminoarylalkynyl, carboxyarylalkynyl, oxyalkynylaryl, thioalkynylaryl, aminoalkynylaryl or carboxyalkynylaryl, oxyalkylene, thioalkylene, aminoalkylene, carboxyalkylene, oxyalkenylene, thioalkenylene, aminoalkenylene, carboxyalkenylene, oxyalkynylene, thioalkynylene, aminoalkynylene, carboxyalkynylene, oxycycloalkylene, thiocycloalkylene, aminocycloalkylene, carboxycycloalkylene, oxycycloalkenylene, thiocycloalkenylene, aminocycloalkenylene, carboxycycloalkenylene, oxyarylene, thioarylene, aminoarylene, carboxyarylene, oxyalkylarylene, thioalkylarylene, aminoalkylarylene, carboxyalkylarylene, oxyarylalkylene, thioarylalkylene, aminoarylalkylene, carboxyarylalkylene, oxyarylalkenylene, thioarylalkenylene, aminoarylalkenylene, carboxyarylalkenylene, oxyalkenylarylene, thioalkenylarylene, aminoalkenylarylene, carboxyalkenylarylene, oxyarylalkynylene, thioarylalkynylene, aminoarylalkynylene, carboxyarylalkynylene, oxyalkynylarylene, thioalkynylarylene, aminoalkynylarylene, carboxyalkynylarylene, heteroarylene, oxyheteroarylene, thioheteroarylene, aminoheteroarylene, carboxyheteroarylene, heteroatom-containing di or polyvalent cyclic moiety, oxyheteroatom-containing di or polyvalent cyclic moiety, thioheteroatom-containing di or polyvalent cyclic moiety, aminoheteroatom-containing di or polyvalent cyclic moiety, carboxyheteroatom-containing di or polyvalent cyclic moiety, disulfide, sulfonamide, and the like.

In another embodiment, maleimides, nadimides, and itaconimides contemplated for use in the practice of the present invention have the structures I, II, or III, where m=1-6, p=0-6, and J is selected from saturated straight chain alkyl or branched chain alkyl, optionally containing optionally substituted aryl moieties as substituents on the alkyl chain or as part of the backbone of the alkyl chain, and where the alkyl chains have up to about 20 carbon atoms;

a siloxane having the structure: —(C(R³)₂)_{d}—{Si(R⁴)₂—O} [symbol] —Si(R⁴)₂—(C(R³)₂)ₑ—, —(C(R³)₂)_{d}—C(R³)—C(O)O—(C(R³)₂)_{d}—{Si(R⁴)₂—O} [symbol] —Si(R⁴)₂—(C(R³)₂) [symbol] —O(O)C—(C(R³)₂)ₑ—, or —(C(R³)₂)_{d}—C(R³)—O(O)C—(C(R³)₂)_{d}—{Si(R⁴)₂—O}_{f}—Si(R⁴)₂—(C(R³)₂)ₑ—C(O)O—(C(R³)₂)ₑ—, where:

each R³ is independently hydrogen, alkyl or substituted alkyl,

each R⁴ is independently hydrogen, lower alkyl or aryl,

d=1-10,

e=1-10, and

f=1-50;

a polyalkylene oxide having the structure:

{(CR₂) [symbol] ᵣ—O—} [symbol] —(CR₂)ₛ—
where:

each R here is independently hydrogen, lower alkyl or substituted alkyl,

r=1-10,

s=1-10, and

f is as defined above;

aromatic groups having the structure:

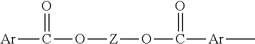

wherein:

each Ar is a monosubstituted, disubstituted or trisubstituted aromatic or heteroaromatic ring having in the range of 3 up to 10 carbon atoms, and

Z is:

saturated straight chain alkylene or branched chain alkylene, optionally containing saturated cyclic moieties as substituents on the alkylene chain or as part of the backbone of the alkylene chain, or

polyalkylene ozides having the structure:

—{(CR₂)ᵣ—O—}_{q}—(CR₂)ₛ—
where:

each R is independently selected from hydrogen or lower alkyl, r and s are each defined as above, and

q falls in the range of 1 up to 50;

di or tri-substituted aromatic moieties having the structure:

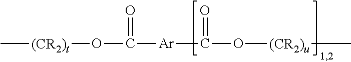

where:

each R is independently selected from hydrogen or lower alkyl,

t falls in the range of 2 up to 10,

u falls in the range of 2 up to 10, and

Ar is as defined above;

aromatic groups having the structure:

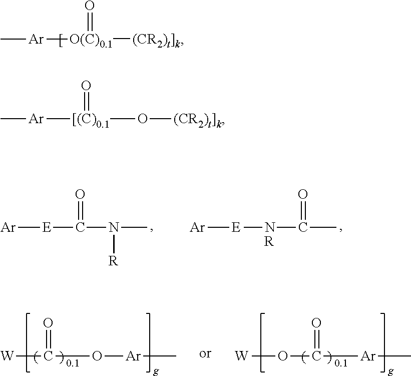

where:

each R is independently selected from hydrogen or lower alkyl,

t=2-10,

k=1, 2 or 3,

g=1 up to about 50,

each Ar is as defined above,

E is —O— or —NR⁵—, where R⁵ is hydrogen or lower alkyl, and

W is straight or branched chain alkyl, alkylene, oxyalkylene, alkenyl, alkenylene, oxyalkenylene, aster, or polyester, a siloxane having the structure —(C(R³)₂)_{d}—{Si(R⁴)₂—O}_{f}—Si(R⁴)₂—(C(R³)₂)ₑ—, —(C(R³)₂)_{d}—C(R³)—C(O)O—(C(R³)₂)_{d}—{Si(R⁴)₂—O}_{f}—Si(R⁴) [symbol] —(C(R³)₂)ₑ—O(O)C—(C(R³)₂)ₑ—, or —(C(R³)₂)_{d}—C(R³)—O(O)C—(C(R³)₂)_{d}—{Si(R⁴)₂—O}_{f}—Si(R⁴)₂—(C(R³)₂)ₑ—C(O)O—(C(R³)₂)ₑ—, where:

each R³ is independently hydrogen, alkyl or substituted alkyl,

each R⁴ is independently hydrogen, lower alkyl or aryl,

d=1-10,

e=1-10, and

f=1-50; and

a polyalkylene oxide having the structure:

—{(CR₂)ᵣ—O—}_{f}—(CR₂)ₛ—
where:

each R is independently hydrogen, alkyl or substituted alkyl,

r=1-10,

s=1-10, and

f is as defined above;

optionally containing substituents selected from hydroxy alkoxy, carboxy, nitrile, cycloalkyl or cycloalkenyl;

a urethane group having the structure:

R⁷—U—C(O)—NR⁶—R⁸—NR⁶C(O)—(O—R⁸—O—C(O)—NR⁶—R⁸—NR⁶—C(O)ᵥ—U—R⁸—
where:

each R⁶ is independently hydrogen or lower alkyl,

each R⁷ is independently an alkyl, aryl, or arylalkyl group having 1 to 18 carbon atoms,

each R⁸ is an alkyl or alkyloxy chain having up to about 100 atoms in the chain, optionally substituted with Ar,

U is —O—, —S—, —N(R)—, or —P(L)_{1,2}—,
where R as defined above, and where each L is independently ═O, ═S, —OR or —R; and

v=0-50;

polcyclic alkenyl; or combinations thereof.

In a particularly desirable aspect of the invention, the maleimide, itaconimide and/or nadimide functional group of the maleimide, itaconimide and/or nadimide compound, respectively, is attached to J, a monovalent radical, or the maleimide, itaconimide and/or nadimide functional groups of the maleimide, itaconimide and/or nadimide compound are separated by J, a polyvalent radical, each of the monovalent radical or the polyvalent radical having sufficient length and branching to render the maleimide, itaconimide and/or nadimide compound a liquid.

In a more specific aspect thereof, J comprises a branched chain alkyl, alkylene or alkylene oxide species having sufficient length and branching to render the maleimide, itaconimide or nadimide compound a liquid, each R² is independently selected from hydrogen or methyl and m is 1, 2 or 3.

Certain maleimide-containing compounds useful in the practice of the present invention include, for example, maleimides having the following structures:

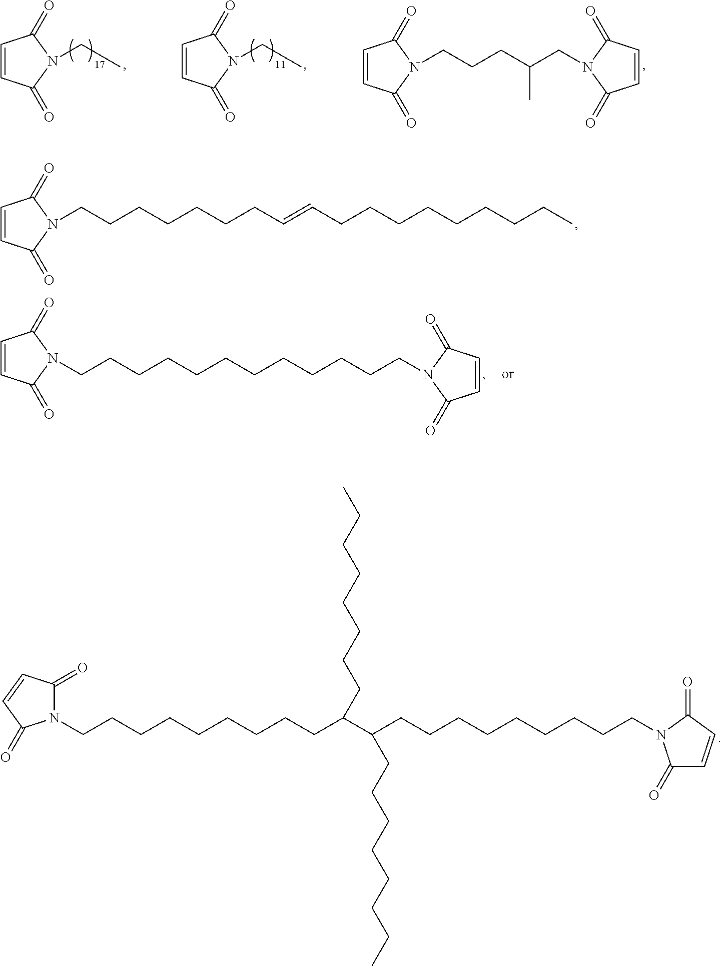

Additional maleimide-containing compounds of formula I include stearyl maleimide, oleyl maleimide, behenyl maleimide, 1,20-bismaleimide-10,11-dioctyl-eicosane, and the like as well as combinations thereof.

Particularly desirable maleimide compounds embraced by formula I include bismaleimides prepared by reaction of maleic anhydride with dimer amides. An exemplary bismaleimide which can be prepared from such dimer amides is 1,20-bismaleimide-10,11-dioctyl-eicosane, which would likely exist in admixture with other isomeric species produced in the ene reactions employed to produce dimer acids. Other bismaleimides contemplated for use in the practice of the present invention include bismaleimides prepared from aminopropyl-terminated polydimethyl siloxanes (such as “PS510” sold by Hüls America, Piscataway, N.J.) polyoxypropylene amines (such as “D-230”, “D-400”, “D-2000” and “T-403”, sold by Texaco Chemical Company, Houston, Tex.), polytetramethyleneoxide-di-p-aminobenzoates (such as the family of such products sold by Air Products, Allentown, Pa., under the trade name “VERSALINK”, e.g., “VERSALINK” P-650), and the like. Preferred maleimide resins of formula I include stearyl maleimide, oleyl maleimide, behenyl maleimide, 1,20-bismaleimide-10,11-dioctyl-eicosane, and the like as well as mixtures of any two or more thereof.

Bismaleimides can be prepared employing techniques well known to those of skill in the art, and as such will not be repeated here.

The metal/carboxylate complex includes a metal selected from Group IVA, Group IVB, Group VIII, and lanthanoid metals. For instance, the metal/carboxylate complex includes carboxylate salts of cobalt, zirconium, lead, cerium, and iron. Illustrative examples of such salts include cobalt benzoate, cobalt octoate, zirconium octoate, cerium octoate, iron octoate, cobalt oleate, cobalt decanoate, cobalt formate, cobalt acetate, cobalt salicylate, cobalt stearate, lead stearate, nickel octoate and cobalt (II) 2-ethylhexanoate.

The metal/carboxylate complex should be present in an amount within the range of 0.01 to about 50 parts per hundred, such as 0.05 to 20 parts per hundred, desirably 0.1 to 10 parts per hundred based on 100 parts of the curable component.

The peroxide is a radical initiator containing an oxygen-oxygen single bond with a low decomposition temperature, such as below about 100° C. Examples of the peroxide include peroxydicarbonate, such as di-(4-tert-butylcyclohexyl) peroxy dicarbonate and aromatic peroxyneodecancate.

The peroxide should be present in an amount within the range of 0.05 to about 20 parts per hundred, such as 5 to 10 parts per hundred, desirably 8 to 10 parts per hundred based on 100 parts of the curable component.

The composition may be cured under temperature conditions of less than 100° C., such as 55-70° C., over a period of time of about 30 to 90 minutes. Under these conditions, electrical conductivity of a semiconductor package in which the inventive composition is used may be measured.

In addition to the maleimides, itaconimides and/or nadimides, additional coreactive monomers or resins may be included, such as epoxies, episulfides, ozetanes, (meth)acrylates, fumarates, maleates, vinyl ethers, vinyl esters, styrene and derivatives thereof, poly(alkenylene)s, allyl amides, norbornenyls, thiolenes, acrylonitriles and combinations thereof.

The (meth)acrylates may be chosen from a host of different compounds. As used herein, the terms (meth)acrylic and (meth)acrylate are used synonymously with regard to the monomer and monomer-containing component. The terms (meth)acrylic and (meth)acrylate include acrylic, methacrylic, acrylate and methacrylate.

The (meth)acrylate component may comprise one or more members selected from a monomer represented by the formula:

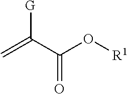

where G is hydrogen, halogen, or an alkyl having from 1 to 4 carbon atoms, R¹ here has from 1 to 16 carbon atoms and is an alkyl, cycloalkyl, alkenyl, cycloalkenyl, alkaryl, aralkyl, or aryl group, optionally substituted or interrupted with silane, silicon, oxygen, halogen, carbonyl, hydroxyl, ester, carboxylic acid, urea, urethane, carbamate, amine, amide, sulfur, sulfonate, or sulfone;

urethane acrylates or ureide acrylates represented by the formula:

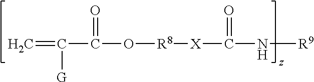

where

G is hydrogen, halogen, or an alkyl having from 1 to 4 carbon atoms;

R⁸ here denotes a divalent aliphatic, cycloaliphatic, aromatic, or araliphatic group, bound through a carbon atom or carbon atoms thereof indicated at the —O— atom and —X— atom or group;

X is —O—, —NH—, or —N(alkyl)-, in which the alkyl radical has from 1 to 8 carbon atoms;

z is 2 to 6; and

R⁹ here is a z-valent cycloaliphatic, aromatic, or araliphatic group bound through a carbon atom or carbon atoms thereof to the one or more NH groups; and

a di or tri-(meth)acrylate selected from polyalkylene glycol di(meth)acrylates, bisphenol-A di(meth)acrylates, bisphenol-F di(meth)acrylates, bisphenol-S di(meth)acrylates, tetrahydrofurane di(meth)acrylates, hexanediol di(meth)acrylate, trimethylol propane tri(meth)acrylate, or combinations thereof.

Suitable polymerizable (meth)acrylate monomers include diethylene glycol di(meth)acrylate, triethylene glycol di(meth)acrylate, tetraethylene glycol di(meth)acrylate, dipropylene glycol di(meth)acrylate, tripropylene glycol di(meth)acrylate, tertrapropylene glycol di(meth)acrylate, pentaerythritol tetra(meth)acrylate, trimethylol propane tri(meth)acrylate, di-pentaerythritol monohydroxypenta(meth)acrylate, pentaerythritol tri(meth)acrylate, bisphenol-A-ethoxylate di(meth)acrylate, trimethylolpropane ethoxylate tri(meth)acrylate, trimethylolpropane propoxylate tri(meth)acrylate, and bisphenol-A-diepoxide dimethacrylate.

Additionally, the (meth)acrylate monomers include tetrahydrofurane (meth)acrylates and di(meth)acrylates, citronellyl (meth)acrylate, hydroxypropyl (meth)acrylate, tetrahydrodicyclopentadienyl (meth)acrylate, triethylene glycol (meth)acrylate, triethylene glycol (meth)acrylate, and combinations thereof.

Of course, (meth)acrylated silicones may also be used, provided the silicone backbone is not so large so as to minimize the effect of (meth)acrylate when cure occurs.

Other acrylates suitable for use herein include the low viscosity acrylates disclosed and claimed in U.S. Pat. No. 6,211,320 (Dershem), the disclosure of which is expressly incorporated herein by reference.

The fumarates include those comprising the following general structure:

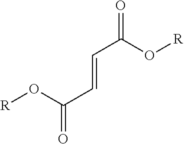

and the maleates include those comprising the following general structure:

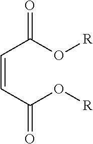

where R for each of the fumarates and maleates may be selected from R¹ as defined above.

Y—{Q_{0,1}—CR═CH₂R}_{q}
where:

q is 1, 2 or 3,

each R here is independently selected from hydrogen or lower alkyl, each Q is independently selected from —O—, —O—C(O)—, —C(O)— or —C(O)—O—, and

Y is defined as J with respect to structures I, II and III above.

Examples of vinyl ethers or vinyl esters embraced by the above generic structure include stearyl vinyl ether, behenyl vinyl ether, eicosyl vinyl ether, isoeicosyl vinyl ether, isotetracosyl vinyl ether, poly(tetrahydrofuran) divinyl ether, tetraethylene glycol divinyl ether, tris-2,4,6-(1-vinyloxybutane-4-oxy-1,3,5-triazine, bis-1,3-(1-vinyloxybutane-4-)oxycarbonyl-benzene (alternately referred to as bis(4-vinyloxybutyl)isophthalate; available from Honeywell Corporation, Morristown, N.J., under the trade name VECTOMER 4010), divinyl ethers prepared by transvinylation between lower vinyl ethers and higher molecular weight di-alcohols.

Particularly desirable divinyl resins include stearyl vinyl ether, behenyl vinyl ether, eicosyl vinyl ether, isoeicosyl vinyl ether, poly(tetrahydrofuran) divinyl ether, divinyl ethers prepared by transvinylation between lower vinyl ethers and higher molecular weight di-alcohols.

Styrene and its derivatives include those comprising the following general structure:

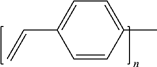

where n is 1-6, attached to J as defined above.

As the allyl amide, a variety of compounds may be chosen, such as those satisfying the criteria set forth above with respect to the maleimides, itaconimides and/or nadimides.

For instance, in a more specific representation, those corresponding to the following structure:

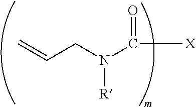

where

R′ is hydrogen, C₁ to about C₁₈ alkyl or oxyalkyl, allyl, aryl, or substituted aryl,

m is 1-6, and

X is as defined above for J.

The norbornenyl component include those comprising the following general structure:

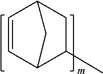

where m is 1-6, attached to J as defined above.

The thiolene component include those comprising the following general structure:

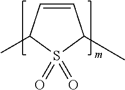

where m is 1-6, attached to J as defined above.

The composition may also include a filler, such as a conductive one, a non-conductive one, or both. When conductive, the filler may be electrically conductive and/or thermally conductive.

The conductive fillers include, for example, silver, nickel, gold, cobalt, copper, aluminum, graphite, silver-coated graphite, nickel-coated graphite, alloys of such metals, and the like, as well as mixtures thereof. Both powder and flake forms of filler may be used in the inventive compositions. Preferably, the flake has a thickness of less than about 2 microns, with planar dimensions of about 20 to about 25 microns. Flake employed ordinarily should have a surface area of about 0.15 to 5.0 m²/g and a tap density of about 0.4 up to about 5.5 g/cc. Powder employed ordinarily should have a diameter of about 0.5 to 15 microns.

Other conductive fillers oftentimes used to confer thermal conductivity include, for example, aluminum nitride, boron nitride, silicon carbide, diamond, graphite, beryllium oxide, magnesia, silica, alumina, and the like. Preferably, the particle size of these fillers will be in the range of about 5 up to about 30 microns, such as about 20 microns.

The conductive filler typically comprises in the range of about 1 weight percent up to about 95 weight percent, such as about 50 weight percent up to about 85 weight percent, desirably about 70 to about 80 weight percent, of the total composition.

The inventive composition may further contain other additives, such as defoaming agents, leveling agents, dyes, and pigments.

The inventive composition may be applied onto the substrate of choice, such as a wafer or die, by conventional application methods, such as by stencil printing, screen printing or spray coating.

In a further aspect of the invention, there are provided methods for adhesively attaching a device to a substrate comprising subjecting a sufficient quantity of an inventive composition positioned between a substrate and a device to conditions suitable to cure the inventive composition. Devices contemplated for use in the practice of the present invention include any surface mount component such as, for example, semiconductor die, resistors, capacitors, and the like.

Preferably, devices contemplated for use in the practice of invention methods are semiconductor dies. Substrates contemplated for use include metal substrates (e.g., lead frames), organic substrates (e.g., laminates, ball grid arrays, and polyamide films), and the like.

### EXAMPLES

Curable compositions with the noted constituents in the respective amounts in grams as set forth below in Table 1 were mixed together for about 10 to 15 minutes at room temperature.

TABLE 1

| Component | | Sample No./Amt (grams) | | | | |
|---|---|---|---|---|---|---|
| Type | Identity | 1 | 2 | 3 | 4 | 5 |
| Malelmide | X-BMI¹ | 10 | 10 | 9.45 | 10.1 | 3.32 |
| (Meth)acrylate | Dicyclopentenyloxyethyl | 1.8 | 1.8 | 1.8 | 1.78 | 2.4 |
| | Acrylate | | | | | |
| | Carbocyclic Acrylate | — | — | — | — | 12.34 |
| Rubber | Polybutadiene | 3.15 | 3.45 | 3 | 3.26 | — |
| Toughener | | | | | | |
| Comonomer | Maleated Polybutadiene | 1.4 | 1.4 | 1.4 | 1.38 | 1 |
| Curing | Cobalt octeate (0.8% solution | 0.2 | 0.2 | 0.2 | — | — |
| Catalyst | in mineral oil) | | | | | |
| | Palladium (meth)acrylate | — | — | — | — | 0.15 |
| Coupling Agent | Beta-(3,4-Epoxycyclohexylethyl | 0.5 | 0.5 | 0.5 | 0.52 | 0.24 |
| | trimethoxysilane) | | | | | |
| | Gamma-Methacryloxypropyl | 0.15 | 0.15 | 0.15 | 0.14 | — |
| | trimethoxysilane | | | | | |
| Free Radical | Di(4′-tert-butyeylohexyl) Peroxy | 1.8 | 1.5 | 1.5 | 1.82 | — |
| Catalyst | dicarbonate | | | | | |
| | Dicomyl peroxide | — | — | — | — | 0.5 |
| Conductive | Silver | 81 | 81 | 82 | 81 | 80 |
| Filler | | | | | | |

Sample Nos. 1-3 are within the scope of the invention, whereas Sample Nos. 4 and 5 are presented for comparative purposes.

An aliqout of each of the samples was placed on a substrate, a silicon die was then placed onto the aliquot, and the assembly was cured at a temperature of 160° C. for 30 minutes.

The samples were evaluated for electrical conductivity by dispensing each sample onto a glass slide, and curing the sample of a temperature of about 60° C. for a period of time of 90 minutes. Once cured, the cured sample was measured to determine its thickness, and then the cured sample is attached to an ohmmeter and its resistance is ohms is measured and recorded. The volume resistivity of each cured sample was then calculated. A lower volume resistivity indicates greater electrical conductivity, and is therefore desirable.

The volume resistivity (ohm-cm) of each sample cured over a 90 minute period at a temperature of about 60° C. is shown below in Table 2. In this test a lower value is indicative of better electrical conductivity.

TABLE 2

| 1 | 2 | 3 | 4 | 5 |
|---|---|---|---|---|
| 0.00064 | 0.00054 | 0.00051 | 0.0435 | None |

What is claimed is:

1. A curable composition comprising:
a. one or more of a maleimide-, nadimide- or itaconimide-compound comprising 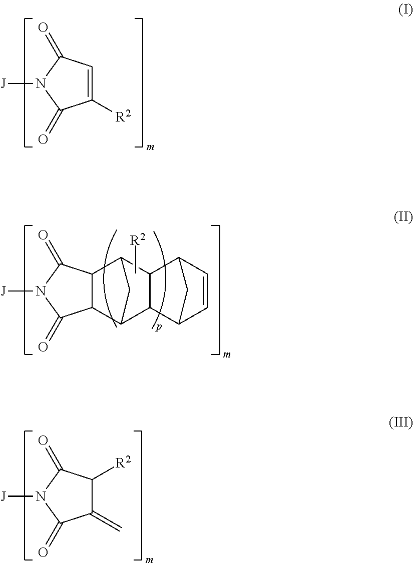
respectively, wherein:
m=1-15,
p=0-15,
each R² is independently selected from hydrogen or lower alkyl, and J comprises a monovalent or a polyvalent moiety comprising organic or organosiloxane radicals, and combinations of two or more thereof; and
b. a curative component comprising the combination of a metal/carboxylate complex and a peroxide.

2. The composition of claim 1, wherein the metal/carboxylate complex includes a metal selected for the group consisting of Group IVA, Group IVB, Group VIII, and lanthanoid metals.

3. The composition of claim 1, wherein the metal/carboxylate complex includes members selected from the group consisting of cobalt benzoate, cobalt octoate, zirconium octoate, cerium octoate, iron octoate, cobalt oleate, cobalt decanoate, cobalt formate, cobalt acetate, cobalt salicylate, cobalt stearate, lead stearate, and nickel octoate.

4. The composition of claim 1, wherein the peroxide is a radical initiator containing an oxygen-oxygen single bond with low decomposition temperature below 100° C.

5. The composition of claim 1, curable under temperature conditions of 55-70° C. over a period of time of about 30 to 90 minutes.

6. The composition of claim 1, further comprising a filler.

7. The composition of claim 1, wherein the filler is electrically conductive.

8. The composition of claim 1, wherein the filler is thermally conductive.

9. The composition of claim 1, wherein the metal/carboxylate complex is a carboxylate salt of a metal selected from the group consisting of cobalt, zirconium, lead, cerium, and iron.

10. The composition of claim 1, wherein the metal/carboxylate complex is present in an amount of j0.05 to 20 parts per hundred.

11. The composition of claim 1, wherein the peroxide is a member selected from the group consisting of a peroxydicarbonate and an aromatic peroxyneodecanoate.

12. The composition of claim 1, wherein the peroxide is present in an amount of 0.05 to 20 parts per hundred.

13. The composition of claim 1, wherein the maleimide-containing compound, the nadimide-containing compound, and the itaconimide-containing compound comprise a maleimide functional group, itaconimide functional group or nadimide functional group, respectively, attached to a monovalent radical or maleimide functional groups, itaconimide functional groups or nadimide functional groups, respectively, separated by a polyvalent radical, each of the monovalent radical or the polyvalent radical having sufficient length and branching to render the maleimide-containing compound, the itaconimide-containing compound or the nadimide-containing compound, respectively, a liquid.

14. The composition of claim 1, wherein J of the maleimide-containing compound, the nadimide-containing compound, and the itaconimide-containing compound is a member selected from the group consisting of
(a) saturated straight chain alkyl or branched chain alkyl, optionally containing optionally substituted aryl moieties as substituents on the alkyl chain or as part of the backbone of the alkyl chain, and wherein the alkyl chains have up to about 20 carbon atoms;
(b) a siloxane having the structure: —(C(R³)₂)_{d}—{Si(R⁴)₂—O}_{f}—Si(R⁴)₂—(C(R³)₂)ₑ—, —(C(R³)₂)_{d}—C(R³)—C(O)O—(C(R³)₂)_{d}—{Si(R⁴)₂—O}_{f}—Si(R⁴)₂—(C(R³)₂)ₑ—O(O)C—(C(R³)₂)ₑ—, or —(C(R³)₂)_{d}—C(R³)—O(O)C—(C(R³)₂)_{d}—{Si(R⁴)₂—O}_{f}—Si(R⁴)₂—(C(R³)₂)ₑ—C(O)O—(C(R³)₂)ₑ—
wherein:
each R³ is independently hydrogen, alkyl or substituted alkyl,
each R⁴ is independently hydrogen, lower alkyl or aryl,
d=1-10,
e=1-10, and
f=1-50;
(c) a polyalkylene oxide having the structure:
{(CR₂)ᵣ—O—}_{f}—(CR₂)ₛ—
wherein:
each R is independently hydrogen, alkyl or substituted alkyl,
r=1-10,
s=1-10, and
f is as defined above;
(d) aromatic groups having the structure: 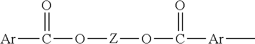
wherein:
each Ar is a monosubstituted, disubstituted or trisubstituted aromatic or heteroaromatic ring having in the range of 3 up to 10 carbon atoms, and
Z is:
(i) saturated straight chain alkylene or branched chain alkylene, optionally containing saturated cyclic moieties as substituents on the alkylene chain or as part of the backbone of the alkylene chain, or
(ii) polyalkylene oxides having the structure:
—{(CR₂)ᵣ—O—}_{q}—(CR₂)ₛ—
wherein:
each R is independently hydrogen, alkyl or substituted alkyl, and r and s are each defined as above, and
q falls in the range of 1 up to 50;
(e) di or tri-substituted aromatic moieties having the structure: 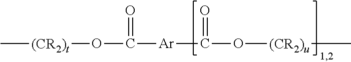
wherein:
each R is independently hydrogen, alkyl or substituted alkyl,
t falls in the range of 2 up to 10,
u falls in the range of 2 up to 10, and
Ar is as defined above;
(f) aromatic groups having the structure: 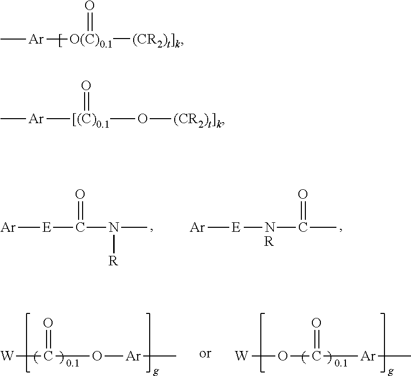
wherein:
each R is independently hydrogen, alkyl or substituted alkyl,
t=2-10,
k=1, 2 or 3,
g=1 up to about 50,
each Ar is as defined above,
E is —O— or —NR⁵—, wherein R⁵ is hydrogen or lower alkyl; and
W is
(i) straight or branched chain alkyl, alkylene, oxyalkylene, alkenyl, alkenylene, oxyalkenylene, ester, or polyester,
(ii) a siloxane having the structure —(C(R³)₂)_{d}—{Si(R⁴)₂—O}_{f}—Si(R⁴)₂—(C(R³)₂)ₑ—, —(C(R³)₂)_{d}—C(R³)—C(O)(—(C(R³)₂)_{d}—{Si(R⁴)₂—O}_{f}—(C(R³)₂)_{d}—{Si(R⁴)₂—O}_{f}—Si(R⁴)₂—(C(R³)₂—(C(R³)₂)ₑ—C(O)O—(C(R³)₂)ₑ—, wherein:
each R³ is independently hydrogen, lower alkyl or aryl,
d=1-10,
e=1-10, and
f=1-50; and
(iii) a polyalkylene oxide having the structure:
—{(CR₂)ᵣ—O—}_{f}—(CR₂)ₛ—
wherein:
each R is independently hydrogen, alkyl or substituted alkyl,
r=1-10,
s=1-10, and
f is as defined above;
optionally containing substituents selected from hydroxy, alkoxy, carboxy, nitrile, cycloalkyl or cycloalkenyl;
(g) a urethane group having the structure:
R⁷—U—C(O)—NR⁶—NR⁶—C(O)—(O—R⁶—O—C(O)—NR⁶—R⁸—NR⁶—C(O))_{z,999 —U—R}⁸—
wherein:
each R⁶ is independently hydrogen or lower alkyl;
each R⁷ is independently an alkyl, aryl, or arylalkyl group having 1 to 18 carbon atoms;
each R⁸ is an alkyl or alkyloxy chain having up to about 100 atoms in the chain, optionally substituted with Ar;
U is —O—, —S—, —N(R)—, or —P(L)_{1,2}—,
wherein R as defined above, and wherein each L is independently ═O, ═S, —OR or —R; and
v=0-50;
(H) polycyclic alkenyl; and combinations thereof.

15. The composition of claim 14, wherein m=1-6, p=0, each R² is independently selected from hydrogen or lower alkyl, and J is a monovalent or polyvalent radical selected from the group consisting of hydrocarbyl, substituted hydrocarbyl, heteroatom-containing hydrocarbyl, substituted heteroatom-containing hydrocarbyl, hydrocarbylene, substituted hydrocarbylene, heteroatom-containing hydrocarbylene, substituted heteroatom-containing hydrocarbylene, polysiloxane, polysiloxane-polyurethane block copolymer, and combinations of two or more thereof, optionally containing one or more linkers selected from the group consisting of a covalent bond, —O—, —S—, —NR—, —O—C(O)—, —O—C(O)—O—, —O—C(O)—NR—, —NR—C(O)—, —NR—C(O)—O—, —NR—C(O)—NR—, —S—C(O)—, —S—C(O)—O—, —S—C(O)—NR—, —(O)—, —S(O)₂——O—S(O)₂—, —O—S(O)₂—O—, —O—S(O)₂—NR—, —O—S(O)(—, —O—S(O)—O—, —O—S(O)—NR—, —O—NR—C(O)—, —O—NR—C(O)—O—, —O—NR—C(O)—NR—, —NR—O—C(O)—, —NR—O—C(O)—O—, —NR—O—C(O)—NR—, —O—NR—C(S)—, —O—NR—C(S)—O—, —O—NR—C(S)—NR—, —NR—O—C(S)—, —NR—O—C(S)—O—, —NR—O—C(S)—NR—, —O—C(S)—, —O—C(S)—O—, —O—C(S)—NR—, —NR—C(S)—, —NR—C(S)—O—, —NR—C(S)—NR—, —S—S(O)₂—, —S—S(O)₂—O—, —S—S(O)₂—NR—, —NR—O—S(O)—, —NR—C(S)—NR—, —NR—O—S(O)—NR—, —NR—O—S(O)₂ —, —NR—O—S(O)₂—O—, —NR—O—S(O)₂—NR—, —O—NR—S(O)—, —O—NR—S(O)—O—, —O—NR—S(O)—NR—, —O—NR—S(O)₂—O—, —O—NR—S(O)₂—NR—, —O—NR—S(O)₂—, —O—P(O)R₂—, —S—P(O)R₂—, —NR—P(O)R₂—, wherein each R is independently hydrogen, alkyl or substituted alkyl, and combination of any two or more thereof.

16. The composition according to claim 1, wherein the maleimide-containing compound, the nadimide-containing compound, and the itaconimide-containing compound comprises a maleimide functional group, nadimide functional group or itaconimide functional group, respectively, attached to a monovalent radical or maleimide functional groups, respectively, separated by a polyvalent radical, each of the monovalent radical or the polyvalent radical having sufficient length and branching to render the maleimide-containing compound, the nadimide-containing compound, or the itaconimide-containing compound, respectively, a liquid.

17. A method for adhesively attaching a chip die to a circuit board, said method comprising:
(a) applying the composition of claim 1 to said chip die,
(b) adjoining said chip die with said circuit board to form an assembly wherein said chip die and said circuit board are separated by the composition applied in step (a), and
(c) subjecting said assembly formed in step (b) to conditions suitable to cure said composition.

18. An article of manufacture comprising a semiconductor chip attached to and in electrical interconnection with a carrier substrate, the semiconductor chip having a first surface and a second surface, with the first surface having electrical contacts arranged in a predetermined pattern thereon for providing electrical engagement with the carrier substrate, and with the second surface having a cured composition of claim 1 disposed on a layer or a portion thereof, so as to provide attachment between the semiconductor chip and the carrier substrate.

19. Reaction products of the composition according to claim 1.
